(19) United States
(12) Patent Application Publication
(10) Pub. No.: US 2003/0194871 A1
(43) Pub. Date: Oct. 16, 2003

(54) Method of stress and damage elimination during formation of isolation device

(75) Inventor: Shu-Ya Hsu, Tao-Liu City (TW)

Correspondence Address: LOWE HAUPTMAN GILMAN & BERNER, LLP, Suite 310, 1700 Diagonal Road, Alexandria, VA, 22314, US

(73) Assignee: Macronix International Co., Ltd.

(21) Appl. No.: 10/121,691

(22) Filed: Apr. 15, 2002

(51) Int. Cl. H01L 21/00; H01L 21/311

(52) U.S. Cl. 438/694

(57) ABSTRACT

The present invention provides a method of stress and damage elimination during formation of a trench isolation device. The method provides a semiconductor substrate and then the semiconductor substrate is etched to form a trench structure. The trench structure is subjected to annealing, such as high temperature or rapid thermal annealing, whereby eliminates stress of the trench structure. It is also applied on forming a side-wall oxide layer at a side-wall of the trench structure and then subjecting the side-wall oxide layer to annealing whereby eliminates oxidation-induced stress of the trench structure.

### BACKGROUND OF THE INVENTION

1. Field of the Invention

The invention relates to a method of stress and damage elimination during the formation of isolation device, and more particularly to a method of stress and damage elimination during the formation of shallow trench isolation. The stress and damage elimination can prevent semiconductor devices from reliability degradation.

2. Description of the Prior Art

It is a conventional method to isolate devices in a integrated circuit by using shallow-trench isolation. Generally, an anisotropic etching process is performed with using silicon nitride as a mask to form steep trenches on a semiconductor substrate. Then, by filling the trenches with oxide, shallow-trench isolations, which have top surfaces are in level with the top surface of the substrate, are formed on the substrate.

FIGS. 1A through 1D are cross-sectional views showing a conventional method forming a shallow-trench isolation.

Referring to FIG. 1A, a pad oxide layer 122 is formed on a silicon substrate 110 for protecting the substrate 110, wherein the pad oxide layer 122 is removed before the formation of a sacrifical oxide layer. A silicon nitride layer 124 is formed on the substrate 110 by performing a chemical vapor deposition (CVD). Then, an etching process is performed on the substrate 110 by using a patterned photoresist layer 128 as a mask to form multitudes of trench structures 130 on the substrate 110, wherein the photoresist layer 128 is removed after the etching process.

Referring to FIG. 1B, a side-wall oxide layer 131 is formed at side walls of the trench structures 130 by performing a thermal oxidation process, and then, a silicon oxide layer 132 is filled in the trench structures 130 and on the surface of the substrate 110.

Referring to FIG. 1C, the silicon oxide layer 132 on the silicon nitride layer 124 is removed by performing a chemical mechanical polishing (CMP) process after a densification process, such as annealing step, is performed on the oxide layer 132 to form multitudes of shallow trench isolation devices 134.

Referring to FIG. 1D, the silicon nitride layer 24 is stripped by using hot phosphoric acid.

However, there is a consideration to stress for applying the conventional process mentioned above on the higher integrated circuit fabrication, such as 0.25-micrometer process. For example, the trench etching may cause stress and damage on the active regions of the semiconductor devices, which may further result in reliability degradation.

### SUMMARY OF THE INVENTION

It is an object of the present invention to provide a method of stress and damage elimination during the formation of trench isolation devices. The high temperature annealing is applied on the formation of trench structure can eliminate stress effect produced by etching method.

It is another object of the present invention to provide a method of preventing the reliability degradation resulted from the formation of the trench isolation devices. The trench structure is subjected to the rapid thermal annealing after the trench etching, which can prevent the semiconductor devices from reliability degradation.

It is another object of the present invention to provide a method of preventing the reliability degradation resulted from the formation of the side-wall oxide layer for trench isolation devices. The side-wall oxide layer is subjected to the rapid thermal annealing after the formation, which can prevent the semiconductor devices from reliability degradation.

In the present invention, a method of stress and damage elimination during formation of a trench isolation device is provided. The method provides a semiconductor substrate and then the semiconductor substrate is etched to form a trench structure. The trench structure is subjected to annealing, such as high temperature or rapid thermal annealing, whereby eliminates stress of the trench structure. It is also applied on forming a side-wall oxide layer at a side-wall of the trench structure and then subjecting the side-wall oxide layer to annealing whereby eliminates oxidation-induced stress of the trench structure.

### BRIEF DESCRIPTION OF THE DRAWINGS

A better understanding of the invention may be derived by reading the following detailed description with reference to the accompanying drawing wherein:

FIGS. 1A-1D are a series of cross-sectional schematic diagrams illustrating the formation of the shallow trench isolation in accordance with the prior art; and

FIGS.2A-2D are a series of cross-sectional schematic diagrams illustrating the treatment of the trench structure in accordance with the present invention.

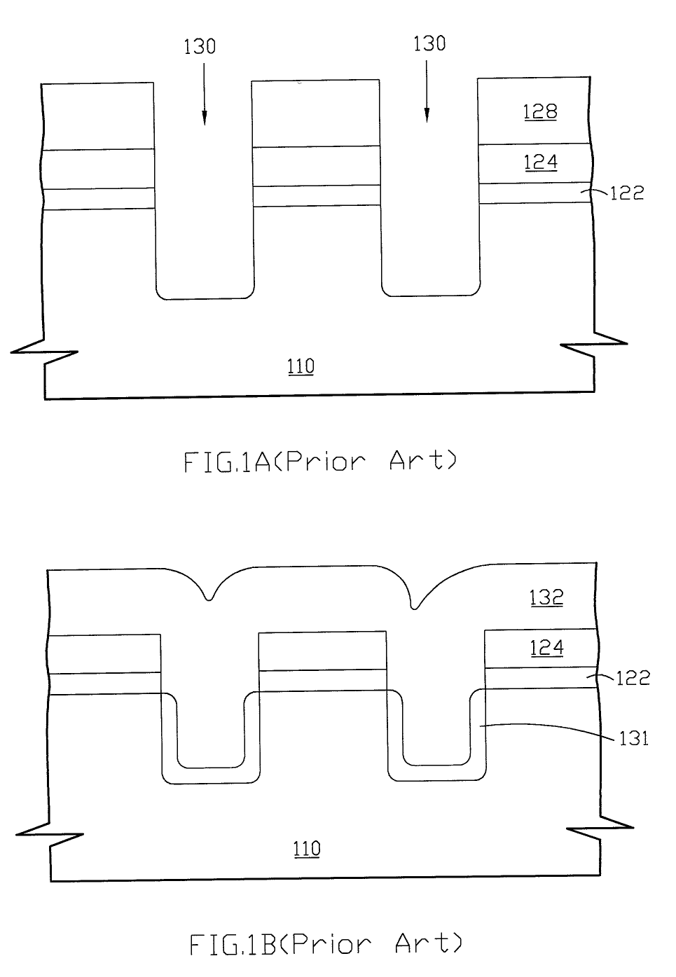

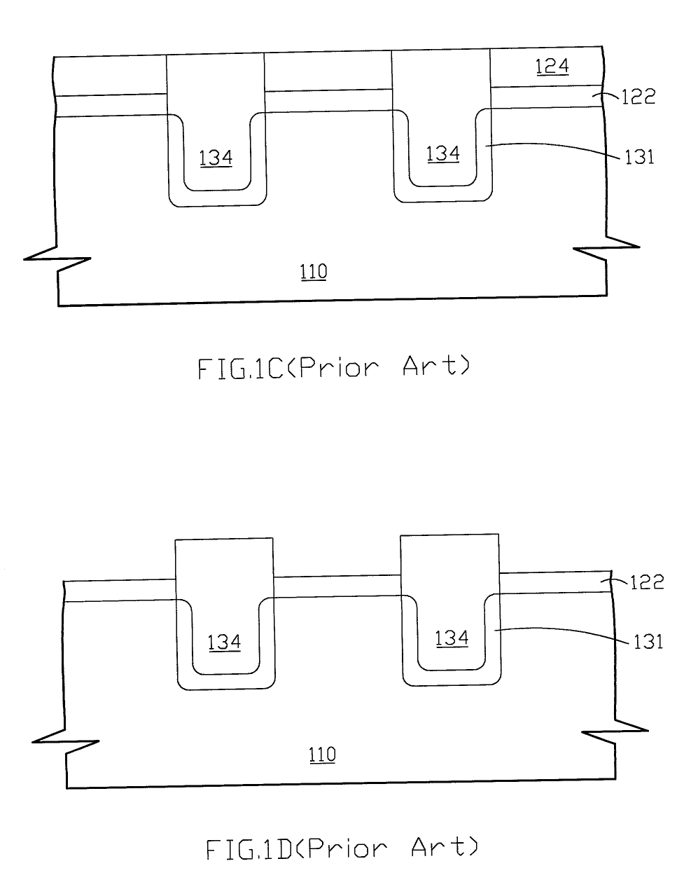

### DESCRIPTION OF THE PREFERRED EMBODIMENT

The semiconductor devices of the present invention are applicable to a board range of semiconductor devices and can be fabricated from a variety of semiconductor materials. While the invention is described in terms of a single preferred embodiment, those skilled in the art will recognize that many steps described below can be altered without departing from the spirit and scope of the invention.

Furthermore, there is shown a representative portion of a semiconductor structure of the present invention in enlarged, cross-sections of the two dimensional views at several stages of fabrication. The drawings are not necessarily to scale, as the thickness of the various layers are shown for clarify of illustration and should not be interpreted in a limiting sense. Accordingly, these regions will have dimensions, including length, width and depth, when fabricated in an actual device.

In the present invention, a method of preventing reliability degradation a semiconductor device during formation of a trench isolation device is provided. The method comprises providing a semiconductor substrate and a pad oxide layer is first formed on the semiconductor substrate. A dielectric layer, such as a silicon nitride layer, is formed on the pad oxide layer. A photo-resist layer is formed on the dielectric layer, which exposes a portion of the dielectric layer where a trench structure is formed. The portion of the dielectric layer and the pad oxide layer is removed to expose the portion of the semiconductor substrate. Then the exposed semiconductor substrate is etched to form the trench structure. The trench structure is then subjected to annealing whereby prevents the semiconductor device from reliability degradation. It is also applied on forming a side-wall oxide layer at a side-wall of the trench structure and then subjecting the side-wall oxide layer to annealing whereby eliminates oxidation-induced stress of the trench structure.

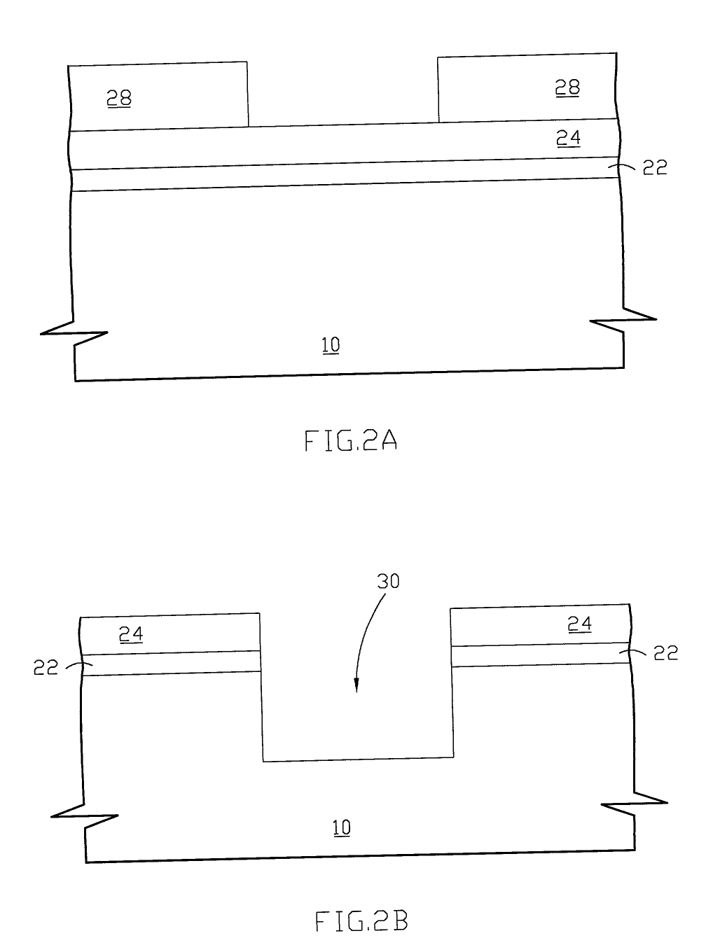

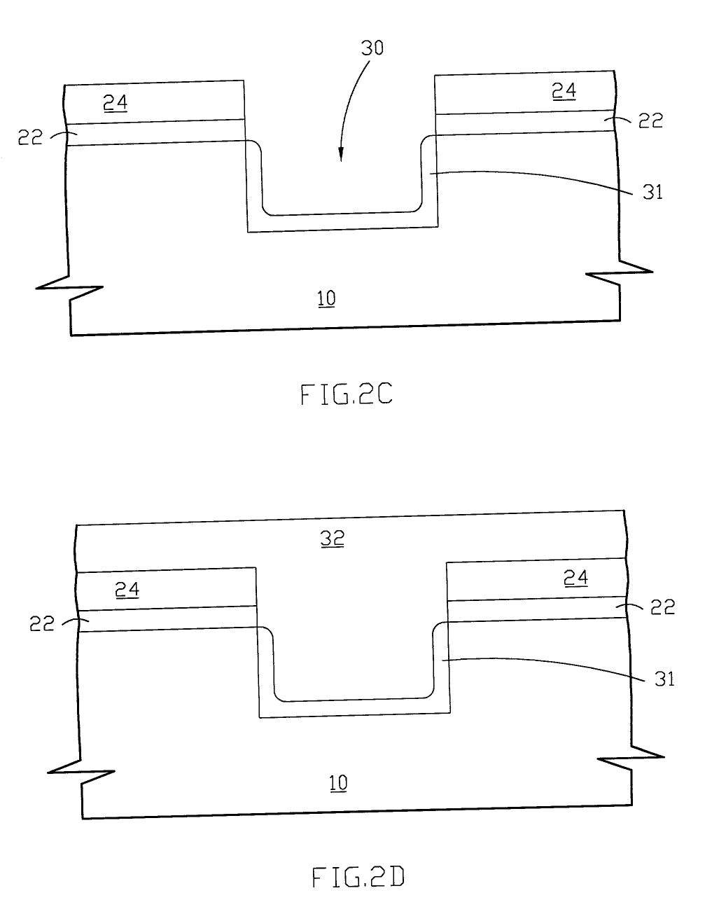

One embodiment of the present invention is depicted in FIGS.2A-2C. First referring to FIG.2A, a semiconductor substrate 10, such as a silicon substrate, is provided and a pad oxide layer 22 is formed thereon for protecting the semiconductor substrate 10. A silicon nitride layer 24 is formed on the pad oxide layer 22 by using the method of chemical vapor deposition (CVD). A patterned photoresist layer 28 as a mask is formed on the silicon nitride layer 24.

Next referring to FIG. 2B, an etching process is performed on the silicon nitride layer 24, the pad oxide layer 22, and the semiconductor substrate 10 in order to form a trench structure 30 on the semiconductor substrate 10. Then the photoresist layer 28 is removed after the etching process.

Referring to FIG. 2C, as a key step of the present invention, before the formation of a side-wall oxide layer 31, the trench structure 30 is subjected to high temperature annealing or rapid thermal annealing. The structure damage of the side-wall of the trench structure 30 may be caused by the process of the trench etching, which may result in the reliability degradation of the semiconductor device. The treatment of high temperature annealing or rapid thermal annealing can repair the structure damage of side-wall of the trench structure 30 and prevent the semiconductor device from the reliability degradation. Then the side-wall oxide layer 31 is formed by any suitable method and the trench structure 30 is filled with silicon oxide (not shown) to form a shallow trench isolation device.

Shown in FIG. 2D is a key step of the present invention. Before the deposition of a silicon oxide layer 32, the side-wall oxide layer 31 is subjected to high temperature annealing or rapid thermal annealing. The treatment of high temperature annealing or rapid thermal annealing can reduce the oxidation-induced stress and prevent the semiconductor device from the reliability degradation. The high temperature annealing or rapid thermal annealing is implemented in an environment containing nitrogen gas, at a temperature in a range of 800° C. and 1200° C., and in a duration of 1 minute to 1 hour. Then the silicon oxide layer 32 is filled in the trench structure 30 and on the surface of the silicon nitride layer 24.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of stress and damage elimination during formation of a trench isolation device, said method comprising:
providing a semiconductor substrate;
etching said semiconductor substrate to form a trench structure; and
subjecting said trench structure to annealing whereby eliminates stress of said trench structure.

2. The method according to claim 1, wherein said annealing comprises high temperature annealing implemented in an environment containing nitrogen gas.

3. The method according to claim 1, wherein said annealing comprises rapid thermal annealing implemented in an environment containing nitrogen gas.

4. The method according to claim 1, wherein said etching step comprises:
forming a pad oxide layer on said semiconductor substrate;
forming a dielectric layer on said pad oxide layer;
forming a photo-resist layer on said dielectric layer, said photo-resist layer exposing a portion of said dielectric layer where said trench structure is formed;
removing said portion of said dielectric layer and said pad oxide layer to expose said portion of said semiconductor substrate; and
etching exposed said semiconductor substrate to form said trench structure.

5. The method according to claim 4, wherein said dielectric layer comprises a silicon nitride layer.

6. The method according to claim 1 further comprising filling said trench structure with an insulating material to form said trench isolation device.

7. The method according to claim 6, wherein said insulating material comprises silicon oxide.

8. A method of the elimination of oxidation-induced stress during formation of a side-wall oxide layer for a trench isolation device, said method comprising:
providing a semiconductor substrate;
etching said semiconductor substrate to form a trench structure;
forming said side-wall oxide layer at a side-wall of said trench structure; and
subjecting said side-wall oxide layer to annealing whereby eliminates said oxidation-induced stress of said trench structure.

9. The method according to claim 8, wherein said annealing comprises high temperature annealing implemented in an environment containing nitrogen gas.

10. The method according to claim 8, wherein said annealing comprises rapid thermal annealing implemented in an environment containing nitrogen gas.

11. The method according to claim 8, wherein said etching step comprises:
forming a pad oxide layer on said semiconductor substrate;
forming a dielectric layer on said pad oxide layer;
forming a photo-resist layer on said dielectric layer, said photo-resist layer exposing a portion of said dielectric layer where said trench structure is formed;
removing said portion of said dielectric layer and said pad oxide layer to expose said portion of said semiconductor substrate; and
etching exposed said semiconductor substrate to form said trench structure.

12. The method according to claim 11, wherein said dielectric layer comprises a silicon nitride layer.

13. The method according to claim 8 further comprising filling said trench structure with an insulating material to form said trench isolation device.

14. The method according to claim 13, wherein said insulating material comprises silicon oxide.

15. A method of stress and damage elimination during formation of a trench isolation device, said method comprising:
providing a semiconductor substrate;
etching said semiconductor substrate to form a trench structure;
subjecting said trench structure to annealing whereby eliminates stress of said trench structure;
forming a side-wall oxide layer at a side-wall of said trench structure; and
subjecting said side-wall oxide layer to annealing whereby eliminates said oxidation-induced stress of said trench structure.

16. The method according to claim 15 further comprising filling said trench structure with an insulating material to form said trench isolation device.

17. The method according to claim 15, wherein said annealing comprises high temperature annealing implemented in an environment containing nitrogen gas.

18. The method according to claim 15, wherein said annealing comprises rapid thermal annealing implemented in an environment containing nitrogen gas.
